(19) United States
(12) Patent Application Publication
(10) Pub. No.: US 2025/0285656 A1
(43) Pub. Date: Sep. 11, 2025

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Dong Yeol YUN, Icheon-si (KR); Nam Kyun PARK, Icheon-si (KR); Jeong Ho YEON, Icheon-si (KR)

(21) Appl. No.: 19/213,699

(22) Filed: May 20, 2025

(30) Foreign Application Priority Data
Jan. 6, 2005 (KR) 10-2025-0001418

(51) Int. Cl. G11C 5/06; H10B 63/00; H10B 63/10; H10N 70/00

(52) U.S. Cl. CPC G11C 5/063; H10B 63/20; H10N 70/021; H10N 70/826; H10N 70/883; H10B 63/10

(57) ABSTRACT

A semiconductor device includes: a first row line extending in a first direction; a first column line extending in a second direction that intersects the first direction; a first memory cell connected between the first row line and the first column line; a second column line located above the first column line and extending in the second direction; and a first resistance pattern located between the first column line and the second column line.

### CROSS-REFERENCE TO RELATED APPLICATION

This application claims priority under 35 U.S.C. § 119 to Korean Patent Application No. 10-2025-0001418 filed on Jan. 6, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first row line extending in a first direction; a first column line extending in a second direction that intersects the first direction; a first memory cell connected between the first row line and the first column line; a second column line located above the first column line and extending in the second direction; and a first resistance pattern located between the first column line and the second column line.

In an embodiment, a method of manufacturing a semiconductor device may include: forming a cell line that extends in a first direction and includes a variable resistance layer; forming a first conductive layer above the cell line; forming a hard mask pattern above the first conductive layer, the hard mask pattern extending in a second direction that intersects the first direction; forming a first column line by etching the first conductive layer using the hard mask pattern, the first column line extending in the second direction; forming a first memory cell by etching the cell line; forming liner patterns on sidewalls of the first memory cell, sidewalls of the first column line, and sidewalls of the hard mask pattern; forming an opening between the liner patterns by removing the hard mask pattern; forming a resistance pattern in the opening; and forming a second column line in the opening.

In an embodiment, a method of manufacturing a semiconductor device may include: forming cell lines that extends in a first direction; forming a first conductive layer on the cell lines; forming hard mask patterns on the first conductive layer, the hard mask patterns extending in a second direction that intersects the first direction; forming first column lines by etching the first conductive layer using the hard mask patterns, the first column lines extending in the second direction;

forming first memory cells by etching the cell lines using the hard mask patterns, the first memory cells being arranged in the first direction and the second direction; forming gap-fill insulating layers between the first column lines adjacent to each other in the first direction; surface-treating the gap-fill insulating layers; forming openings between the gap-fill insulating layers by removing the hard mask patterns; and forming second column lines in the openings.

### BRIEF DESCRIPTION OF THE DRAWINGS

FIGS. 1A, 1B, and 1C are diagrams illustrating the structure of a semiconductor device in accordance with an embodiment.

FIGS. 2A and 2B are diagrams illustrating the structure of a semiconductor device in accordance with an embodiment.

FIGS. 3A, 4A, 5A, 6A, and 7A, FIGS. 3B, 4B, 5B, 6B, and 7B, and FIGS. 3C, 4C, 5C, 6C, and 7C are diagrams for describing a method of manufacturing a semiconductor device in accordance with an embodiment.

FIGS. 8A, 8B, 8C, 8D, and 8E are diagrams for describing a method of manufacturing a semiconductor device in accordance with an embodiment.

FIGS. 9A, 9B, and 9C are diagrams for describing a method of manufacturing a semiconductor device in accordance with an embodiment.

### DETAILED DESCRIPTION

Various embodiments are directed to a semiconductor device having a stable structure and improved characteristics and a method of manufacturing the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B). Moreover, a first element “on” a second element indicates that the first element can be “directly on” the second element, or that at least one intervening element can be interposed between the first and second elements.

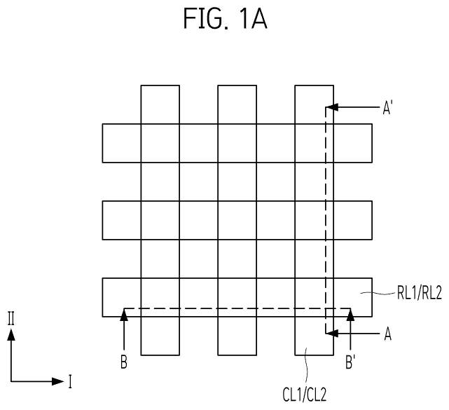

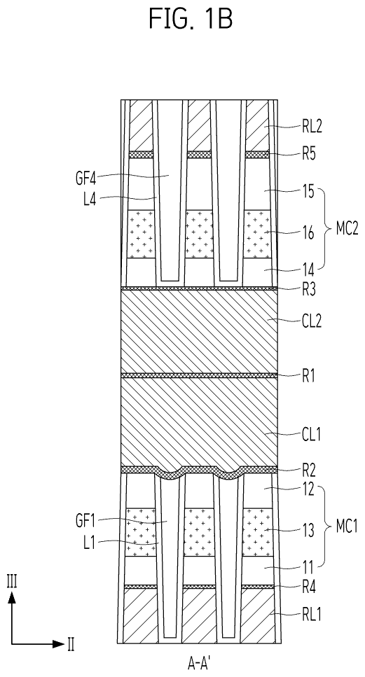

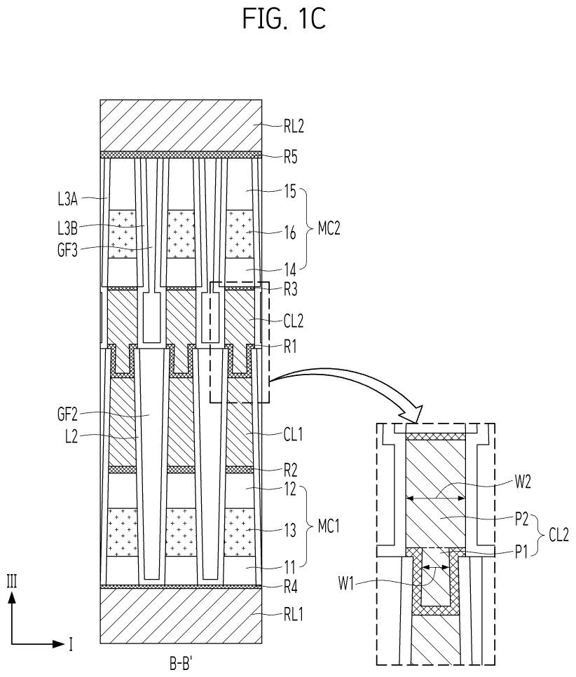

FIGS. 1A to 1C are diagrams illustrating the structure of a semiconductor device in accordance with an embodiment. FIG. 1A is a plan view, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device may include a first row line RL1, a first column line CL1, a first memory cell MC1, a second column line CL2, and a first resistance pattern R1. The semiconductor device may further include at least one of a second row line RL2, a second memory cell MC2, a second resistance pattern R2, a third resistance pattern R3, a fourth resistance pattern R4, a fifth resistance pattern R5, a first liner pattern L1, a second liner pattern L2, third liner patterns L3A and L3B, a fourth liner pattern L4, a first gap-fill insulating layer GF1, a second gap-fill insulating layer GF2, a third gap-fill insulating layer GF3, or a fourth gap-fill insulating layer GF4.

The first row line RL1 and the second row line RL2 may extend in a first direction I, and the first column line CL1 and the second column line CL2 may extend in a second direction II intersecting the first direction I. The first row line RL1, the first column line CL1, the second column line CL2, and the second row line RL2 may be sequentially stacked along a third direction III. The third direction III may be a direction perpendicular to a plane defined by the first direction I and the second direction II. The first and second row lines RL1 and RL2 may be word lines, and the first and second column lines CL1 and CL2 may be bit lines. Alternatively, the first and second row lines RL1 and RL2 may be bit lines, and the first and second column lines CL1 and CL2 may be word lines.

The first memory cell MC1 may be connected between the first row line RL1 and the first column line CL1, and the second memory cell MC2 may be connected between the second row line RL2 and the second column line CL2. The first memory cell MC1 may be a resistive memory cell including a variable resistance layer 13. Each of the first memory cells MC1 may include a select element, or a memory element, or both. As an example, each of the first memory cells MC1 may include a first electrode 11, a second electrode 12, and a variable resistance layer 13, and the variable resistance layer 13 may be located between the first electrode 11 and the second electrode 12.

The variable resistance layer 13 may have characteristics that it reversibly transitions between different resistance states depending on a voltage or a current applied to the first memory cell MC1. As an example, when the variable resistance layer 13 has a low resistance state, data ‘1’ may be stored, and when the variable resistance layer 13 has a high resistance state, data ‘0’ may be stored.

As an example, the variable resistance layer 13 may include a resistive material. An electrical path is generated or disappears in the variable resistance layer 13, such that data may be stored. As an example, the variable resistance layer 13 may include transition metal oxide or include metal oxide such as a perovskite-based material.

As an example, the variable resistance layer 13 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

As an example, the variable resistance layer 13 may include a phase change material or include a chalcogenide-based material. The variable resistance layer 13 may change its phase according to a program operation. As an example, the variable resistance layer 13 may have a low resistance crystalline state through a set operation. As an example, the variable resistance layer 13 may have a high resistance amorphous state through a reset operation. Accordingly, the data may be stored in the memory cell using a resistance difference depending on a phase of the variable resistance layer 13.

As an example, the variable resistance layer 13 may include a variable resistance material whose resistance changes without a phase change or include a chalcogenide-based material. The variable resistance layer 13 may maintain its phase after the program operation. As an example, the variable resistance layer 13 may have an amorphous state, and may maintain the amorphous state without changing to a crystalline state after the program operation. A threshold voltage of the memory cell may be changed depending on a program voltage applied to the memory cell, and the memory cell may be programmed to at least two states. As an example, the memory cell may be programmed to a set state or a reset state using program voltages having different polarities. Accordingly, the data may be stored in the memory cell using a difference in the threshold voltage of the memory cell.

The first electrode 11 may be electrically connected to the first row line RL1. The second electrode 12 may be electrically connected to the first column line CL1. The first electrode 11 and the second electrode 12 may each include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SIC), silicon carbonitride (SiCN), aluminum (Al), copper (Cu), zinc (Zn), nickel (Ni), cobalt (Co), lead (Pb), platinum (Pt), molybdenum (Mo), ruthenium (Ru), or the like, or include one or more combinations thereof. The first row line RL1 and the first column line CL1 may each include metal such as tungsten (W) or molybdenum (Mo).

The second memory cells MC2 may each have a similar structure to the first memory cells MC1. Each of the second memory cells MC2 may include a first electrode 14, a second electrode 15, and a variable resistance layer 16, and the variable resistance layer 16 may be located between the first electrode 14 and the second electrode 15.

The first liner patterns L1 may be located on sidewalls of the first memory cells MC1 adjacent to each other in the second direction II, and may extend along sidewalls of the first row lines RL1. The first gap-fill insulating layers GF1 may be located between the first memory cells MC1 adjacent to each other in the second direction II, and may extend between the first row lines RL1. For example, each of the first gap-fill insulating layers GF1 may be located between a pair of the first memory cells MC1 adjacent to each other in the second direction II, and may extend between a pair of the first row lines RL1 adjacent to each other in the second direction II.

The second liner patterns L2 may be located on sidewalls of the first memory cells MC1 adjacent to each other in the first direction I, and may extend along sidewalls of the first column lines CL1. The second liner pattern L2 may extend along a sidewall of the second column line CL2, and may cover a portion of the sidewall of the second column line CL2. Specifically, the second liner pattern L2 may cover a sidewall of a corresponding (e.g., abutting) one of the first memory cells MC1, a sidewall of a corresponding (e.g., abutting) one of the first column lines CL1, and a portion of a sidewall of a corresponding (e.g., adjacent to) one of the second column lines CL2. For example, the second liner pattern L2 may cover a pair of sidewalls of an adjacent pair of the first memory cell MC1 in the first direction I, a pair of sidewalls of an adjacent pair of the first column lines CL1 in the first direction I, and portions of sidewalls of an adjacent pair of the second column lines CL2 in the first direction I. The second gap-fill insulating layers GF2 may be located between the first memory cells MC1 adjacent to each other in the first direction I, and may extend between the first column lines CL1. For example, each of the second gap-fill insulating layers GF2 may be located between a pair of the first memory cells MC1 adjacent to each other in the first direction I, and may extend between a pair of the first column lines CL1 adjacent to each other in the first direction I.

The third liner patterns L3A may be located on sidewalls of the second memory cells MC2 adjacent to each other in the first direction I. The third liner patterns L3B may be located on the third liner patterns L3A, and may extend along sidewalls of the second column lines CL2. The third gap-fill insulating layers GF3 may be located between the second memory cells MC2 adjacent to each other in the first direction I, and may extend between the second column lines CL2.

The fourth liner patterns L4 may be located on sidewalls of the second memory cells MC2 adjacent to each other in the second direction II, and may extend along sidewalls of the second row lines RL2. The fourth gap-fill insulating layers GF4 may be located between the second memory cells MC2 adjacent to each other in the second direction II, and may extend between the second row lines RL2.

The first to fourth liner patterns L1 to L4 may each include nitride. The first to fourth gap-fill insulating layers GF1 to GF4 may each include oxide.

The first resistance pattern R1 may be located between the first column line CL1 and the second column line CL2. The second column line CL2 may be located above the first column line CL1, and the first resistance pattern R1 may extend in the second direction II. For example, the first resistance pattern R1 may extend along an upper surface of the first column line CL1 and a lower surface of the second column line CL2. The second column line CL2 may be electrically connected to the first column line CL1 through the first resistance pattern R1.

The first resistance pattern R1 is used to reduce damage to the memory cells MC1 and MC2 due to a spike current, and may be a high resistivity pattern. The first resistance pattern R1 may include a material having a higher resistivity than the first and second column lines CL1 and CL2. As an example, the first and second column lines CL1 and CL2 may each include tungsten (W), molybdenum (Mo), or the like, and the first resistance pattern R1 may include at least one of tungsten nitride (WN), tungsten silicon nitride (WSIN), molybdenum nitride (MoN), molybdenum silicon nitride (MoSiN), titanium nitride (TiN), or titanium chloride (TiCl₄).

The first resistance pattern R1 may be located between the first column line CL1 and the second column line CL2 and between the second column line CL2 and the second liner patterns L2. The first resistance pattern R1 may partially cover the sidewall of the second column line CL2. The second column line CL2 may include a first portion P1 and a second portion P2. The first resistance pattern R1 may cover a bottom surface and a sidewall of the first portion P1. The first resistance pattern R1 may not cover the second portion P2. The second portion P2 may be covered by the third liner pattern L3B. For example, the first resistance pattern R1 may cover a pair of opposing sidewalls of the first portion P1 that are arranged in the first direction I and a bottom surface of the first portion P1.

The first portion P1 and the second portion P2 may have different widths. The first portion P1 may have a first width W1, the second portion P2 may have a second width W2, and the second width W2 may be greater than the first width W1. The first width W1 and the second width W2 may be different from each other by a thickness of the first resistance pattern R1. As the first width W1 decreases by the thickness of the first resistance pattern R1, an area associated with contact resistance between the first column line CL1 and the second column line CL2 may decrease compared to that without including the first resistance pattern R1 between the first and second column lines CL1 and CL2. In addition, the resistivity of the first resistance pattern R1 may be greater than that of each of the first and second column lines CL1 and CL2. As a result, contact resistance between the first column line CL1 and the second column line CL2 may increase compared to that without including the first resistance pattern R1 between the first and second column lines CL1 and CL2. Accordingly, the damage to the memory cells MC1 and MC2 due to the spike current may be further reduced.

The second resistance pattern R2 may be located between the first memory cells MC1 and the first column line CL1, and may extend in the second direction II along a lower surface of the first column line CL1. The third resistance pattern R3 may be located between the second memory cells MC2 and the second column line CL2, and may extend in the second direction II along an upper surface of the second column line CL2. The fourth resistance pattern R4 may be located between the first row line RL1 and the first memory cells MC1, and may extend in the first direction I along an upper surface of the first row line RL1. The fifth resistance pattern R5 may be located between the second row line RL2 and the second memory cells MC2, and may extend in the first direction I along a lower surface of the second row line RL2.

The second to fifth resistance patterns R2 to R5 are used to reduce damage to the memory cells MC1 and MC2 due to a spike current, and may be relatively high resistivity patterns. The second to fifth resistance patterns R2 to R5 may each include a material having a higher resistivity than the first and second column lines CL1 and CL2 and/or the first and second row lines RL1 and RL2. As an example, the second to fifth resistance patterns R2 to R5 may each include at least one of tungsten nitride (WN), tungsten silicon nitride (WSiN), molybdenum nitride (MoN), molybdenum silicon nitride (MoSiN), titanium nitride (TiN), or titanium chloride (TiCl₄). According to the structure described above, a first memory cell array including the first memory cells MC1 and a second memory cell array including the second memory cells MC2 may share the first and second column lines CL1 and CL2 with each other. The semiconductor device may reduce the damage to the memory cells MC1 and MC2 due to the spike current by including at least one of the first to fifth resistance patterns R1 to R5.

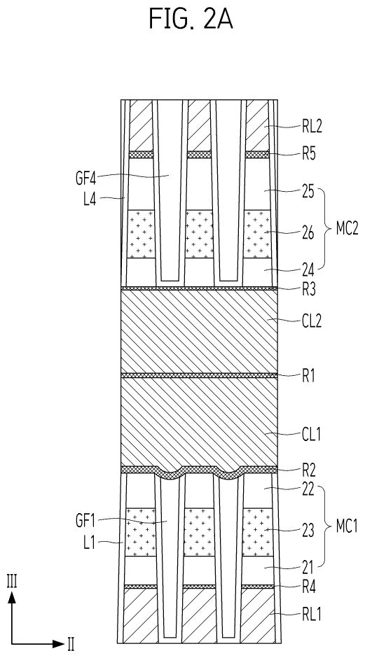

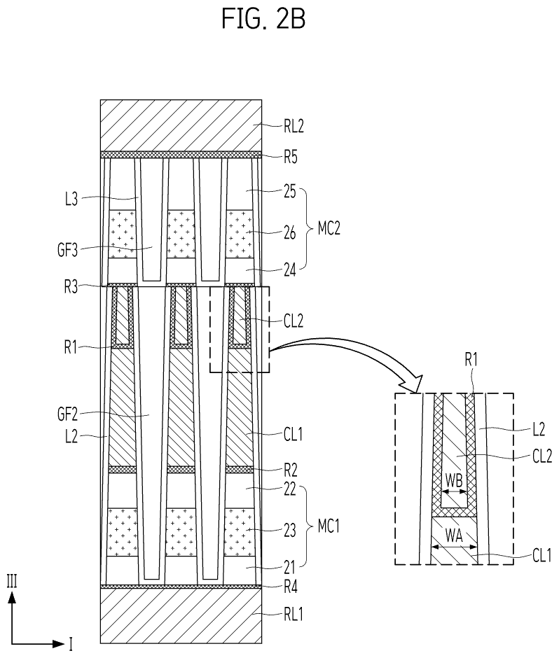

FIGS. 2A and 2B are diagrams illustrating the structure of a semiconductor device in accordance with an embodiment. FIG. 2A is a cross-sectional view in the first direction I, and FIG. 2B is a cross-sectional view in the second direction II. Hereinafter, the content overlapping with the previously described content may be omitted for the interest of brevity.

Referring to FIGS. 2A and 2B, the semiconductor device may include a first row line RL1, a first column line CL1, a first memory cell MC1, a second column line CL2, and a first resistance pattern R1. The semiconductor device may further include at least one of a second row line RL2, a second memory cell MC2, a second resistance pattern R2, a third resistance pattern R3, a fourth resistance pattern R4, a fifth resistance pattern R5, a first liner pattern L1, a second liner pattern L2, a third liner pattern L3, a fourth liner pattern L4, a first gap-fill pattern GF1, a second gap-fill insulating layer GF2, a third gap-fill insulating layer GF3, or a fourth gap-fill insulating layer GF4.

The first memory cell MC1 may be connected between the first row line RL1 and the first column line CL1, and the second memory cell MC2 may be connected between the second row line RL2 and the second column line CL2. The first memory cell MC1 may include a first electrode 21, a second electrode 22, and a variable resistance layer 23. The second memory cell MC2 may include a first electrode 24, a second electrode 25, and a variable resistance layer 26.

The first liner patterns L1 and the first gap-fill insulating layers GF1 may be located between the first memory cells MC1 adjacent to each other in the second direction II. The first liner patterns L1 and the first gap-fill insulating layers GF1 may extend along sidewalls of the first row lines RL1. The fourth liner patterns L4 and the fourth gap-fill insulating layers GF4 may be located between the second memory cells MC2 adjacent to each other in the second direction II. The fourth liner patterns L4 and the fourth gap-fill insulating layers GF4 may extend along sidewalls of the second row lines RL2.

The second liner patterns L2 may be located on sidewalls of first memory cells MC1 adjacent to each other in the first direction I. The second liner patterns L2 may extend along sidewalls of the first column lines CL1 and sidewalls of the second column lines CL2. In some embodiments, each of the second liner patterns L2 may cover a sidewall (e.g., substantially an entire sidewall) of a corresponding (e.g., abutting) one of the first memory cells MC, a sidewall (e.g., substantially an entire sidewall) of a corresponding (e.g., abutting) one of the first column lines CL1, and a sidewall (e.g., substantially an entire sidewall) of a corresponding (e.g., adjacent to) one of the second column lines CL2. The second gap-fill insulating layers GF2 may be located between the first memory cells MC1 adjacent to each other in the first direction I. The second gap-fill insulating layers GF2 may extend between the first column lines CL1 and between the second column lines CL2. The third liner patterns L3 and the third gap-fill insulating layers GF3 may be located between the second memory cells MC2 adjacent to each other in the first direction I.

The first resistance pattern R1 may be located between the first column line CL1 and the second column line CL2 and between the second column line CL2 and the second liner patterns L2. The first resistance pattern R1 may cover a lower surface and the sidewall of the second column line CL2. The first resistance pattern R1 may extend in the second direction II along an upper surface of the first column line CL1 and a lower surface of the second column line CL2, and may extend along the sidewall of the second column line CL2.

The first resistance pattern R1 may entirely cover the sidewall of the second column line CL2. For example, the first resistance pattern R1 may substantially entirely cover a pair of opposing sidewalls of the second column line CL2 that are arranged in the first direction I and a bottom surface of the second column line CL2. An upper surface of the second column line CL2 and an upper surface of the first resistance pattern R1 may be located at substantially the same level. In other words, an upper surface of the second column line CL2 and an upper surface of the first resistance pattern R1 may be substantially coplanar with each other. The upper surface of the second column line CL2 and an upper surface of the second gap-fill insulating layer GF2 may be located at substantially the same level. For example, a level difference between an upper surface of the second column line CL2 and an upper surface of the first resistance pattern R1 may be not greater than 5%, or 3%, or 1% of a height of the second column line CL2 in the third direction III.

The first column line CL1 and the second column line CL2 may have different widths. The first column line CL1 may have a first width WA, the second column line CL2 may have a second width WB, and the second width WB may be smaller than the first width WA. The first width WA and the second width WB may be different from each other by a thickness of the first resistance pattern R1. As the second width WB decreases by the thickness of the first resistance pattern R1, an area associated with contact resistance between the first column line CL1 and the second column line CL2 may decrease compared to that without including the first resistance pattern R1 between the first and second column lines CL1 and CL2. In addition, the resistivity of the first resistance pattern R1 may be greater than that of each of the first and second column lines CL1 and CL2. As a result, resistance between the first column line CL1 and the second column line CL2 may increase compared to that without including the first resistance pattern R1 between the first and second column lines CL1 and CL2. Accordingly, the damage to the memory cells MC1 and MC2 due to the spike current may be further reduced.

The second resistance pattern R2 may be located between the first memory cells MC1 and the first column line CL1, the third resistance pattern R3 may be located between the second memory cells MC2 and the second column line CL2, the fourth resistance pattern R4 may be located between the first row line RL1 and the first memory cells MC1, and the fifth resistance pattern R5 may be located between the second row line RL2 and the second memory cells MC2.

According to the structure described above, a first memory cell array including the first memory cells MC1 and a second memory cell array including the second memory cells MC2 may share the first and second column lines CL1 and CL2 with each other. The semiconductor device may reduce the damage to the memory cells MC1 and MC2 due to the spike current by including at least one of the first to fifth resistance patterns R1 to R5.

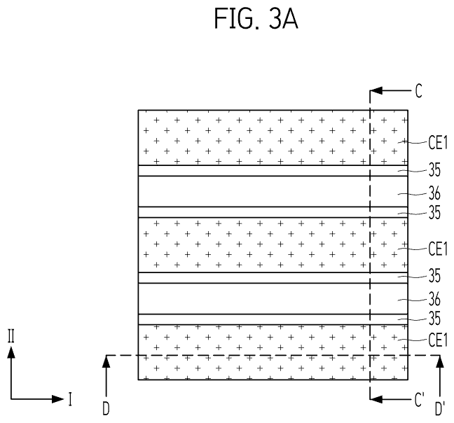

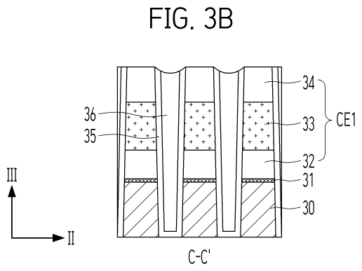

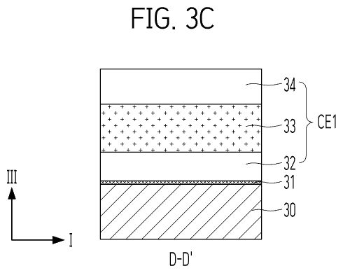

FIGS. 3A, 4A, 5A, 6A, and 7A, FIGS. 3B, 4B, 5B, 6B, and 7B, and FIGS. 3C, 4C, 5C, 6C, and 7C are diagrams for describing a method of manufacturing a semiconductor device in accordance with an embodiment. FIGS. 3A, 4A, 5A, 6A, and 7A are plan views, FIGS. 3B, 4B, 5B, 6B, and 7B are cross-sectional views taken along lines C-C′ of FIGS. 3A, 4A, 5A, 6A, and 7A, respectively, and FIGS. 3C, 4C, 5C, 6C, and 7C are cross-sectional views taken along lines D-D′ of FIGS. 3A, 4A, 5A, 6A, and 7A, respectively. Hereinafter, the content overlapping with the previously described content may be omitted for the interest of brevity.

Referring to FIGS. 3A to 3C, first row lines 30 and first cell lines CE1 extending in the first direction I are formed. The first cell line CE1 may include a first electrode 32, a first variable resistance layer 33, and a second electrode 34. A resistance pattern 31 may be located between the first row line 30 and the first cell line CE1. The resistance pattern 31 may extend in the first direction I between the first row line 30 and the first cell line CE1.

Subsequently, first liner patterns 35 may be formed on sidewalls of the first cell lines CE1 and the first row lines 30. Subsequently, first gap-fill insulating layers 36 may be formed between the first cell lines CE1 adjacent to each other in the second direction II.

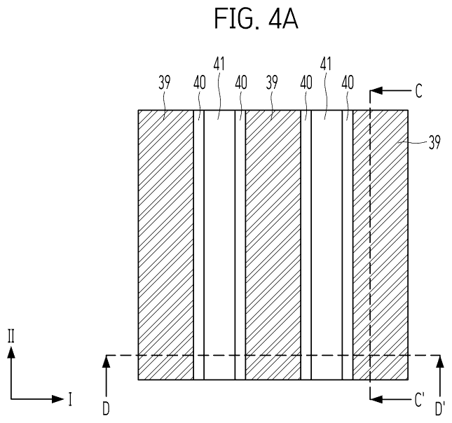

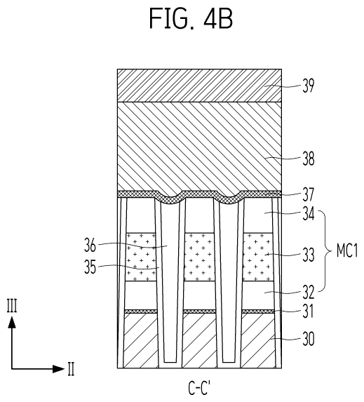

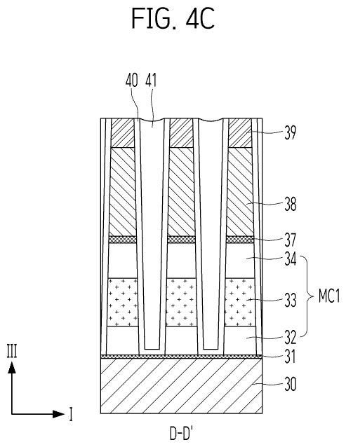

Referring to FIGS. 4A to 4C, a resistance layer, a first conductive layer, and a hard mask layer may be formed above the first cell lines CE1 and the first gap-fill insulating layers 36. For example, the first conductive layer may be formed on the resistance layer and above the first cell lines CE1, and the hard mask layer may be formed on the first conductive layer. Subsequently, hard mask patterns 39 extending in the second direction II may be formed on the first conductive layer by etching the hard mask layer. Subsequently, first column lines 38 extending in the second direction II may be formed by etching the first conductive layer using the hard mask patterns 39 as etching barriers. Subsequently, a resistance pattern 37 may be formed by etching the resistance layer, and first memory cells MC1 may be formed by etching the first cell lines CE1.

Subsequently, second liner patterns 40 may be formed on sidewalls of the first memory cells MC1, the resistance patterns 37, the first column lines 38, and the hard mask patterns 39. Specifically, a pair of adjacent second liner patterns 40 in the first direction I may be formed on a pair of sidewalls of a corresponding one (e.g., abutting) of the first memory cells MC1, a pair of sidewalls of a corresponding one (e.g., abutting) of the first column lines 38, and a pair of sidewalls of a corresponding one (e.g., abutting) of the hard mask patterns 39. The second liner patterns 40 may each include a different material from the hard mask pattern 39. As an example, the hard mask pattern 39 may include a material having a high etching selectivity with respect to the second liner patterns 40. The second liner patterns 40 may each include nitride, and the hard mask pattern 39 may include polysilicon or oxide.

Subsequently, second gap-fill insulating layers 41 may be formed between the first memory cells MC1 and between the first column lines 38 that are adjacent to each other in the first direction I. The second gap-fill insulating layers 41 may extend in the second direction II between the hard mask patterns 39 adjacent to each other in the first direction I.

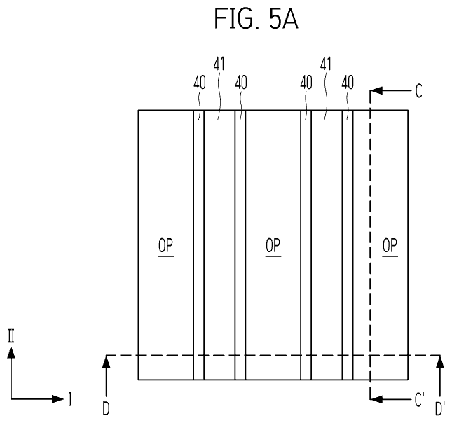

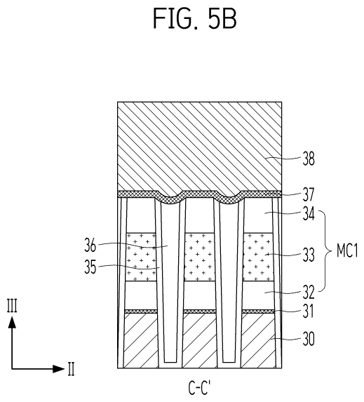

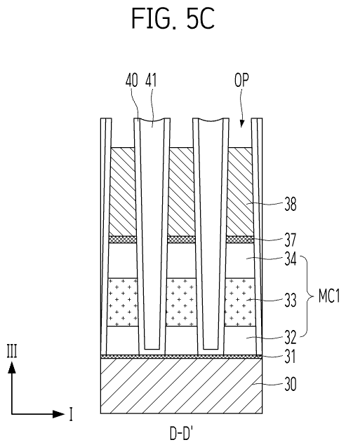

Referring to FIGS. 5A to 5C, openings OP may be formed between the second liner patterns 40 by removing the hard mask patterns 39. For example, each of the openings OP may be formed by removing a corresponding one of the hard mask patterns 39 between an adjacent pair of the second liner patterns 40 in the first direction I. The hard mask patterns 39 may be selectively etched using a difference in etching selectivity between the hard mask patterns 39 and the second liner patterns 40 and a difference in etching selectivity between the hard mask patterns 39 and the second gap-fill insulating layers 41. As an example, the hard mask patterns 39 may be wet-etched using a dip-out process. The opening OP may extend in the second direction II, and the first column lines 38 may be exposed through the opening OP.

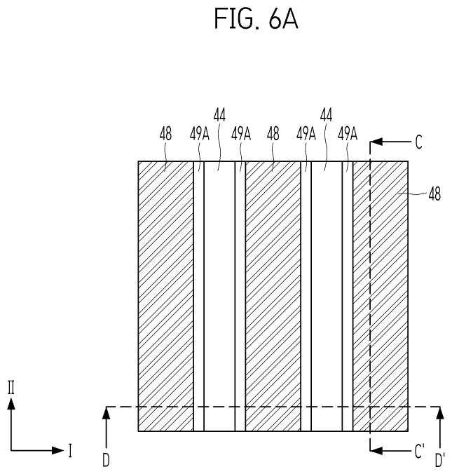

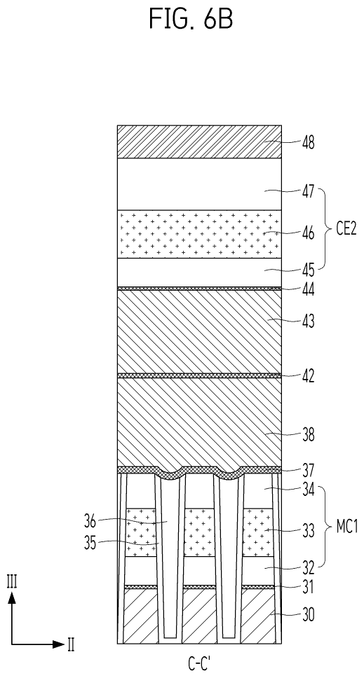

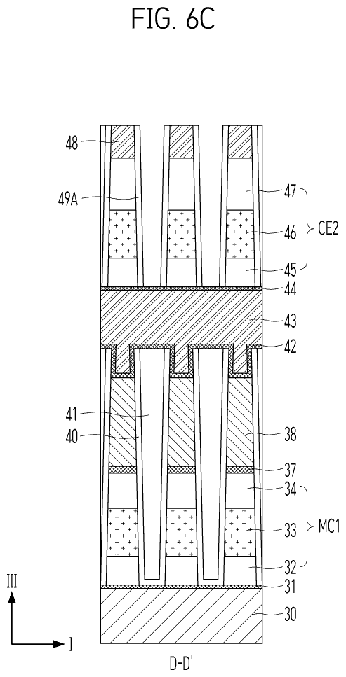

Referring to FIGS. 6A to 6C, a resistance layer 42 may be formed along a surface of the first column line 38 and surfaces of the second liner patterns 40 exposed through the opening OP. The resistance layer 42 may be formed along a profile of the opening OP.

Subsequently, a second conductive layer 43 is formed. The second conductive layer 43 may be formed to fill the opening OP. Subsequently, a resistance layer 44 may be formed on the second conductive layer 43.

Subsequently, a cell stack may be formed on the resistance layer 44, and hard mask patterns 48 may be formed on the cell stack. The hard mask patterns 48 may be located to correspond to the first column lines 38, and may extend in the second direction II. Subsequently, second cell lines CE2 may be formed by etching the cell stack using the hard mask patterns 48 as etching barriers. Each of the second cell lines CE2 may extend in the second direction II, and may include a first electrode 45, a variable resistance layer 46, and a second electrode 47.

Subsequently, third liner patterns 49A may be formed on sidewalls of the hard mask patterns 48 and sidewalls of the second cell lines CE2.

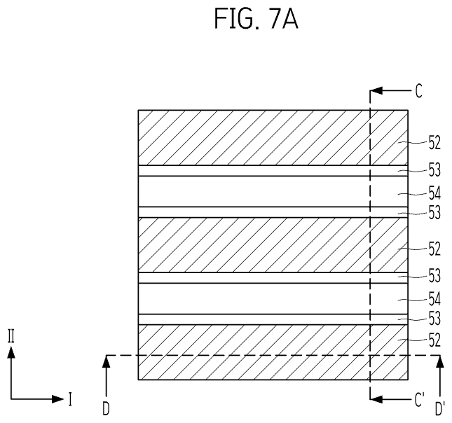

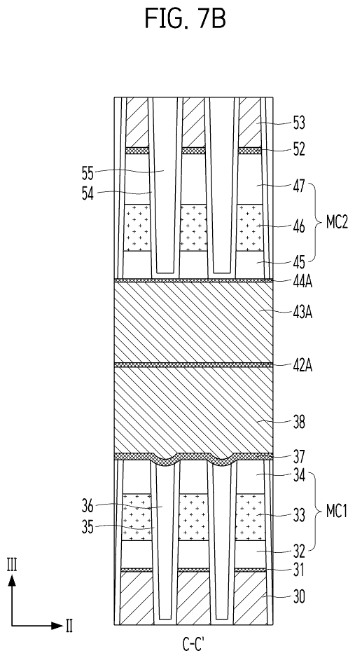

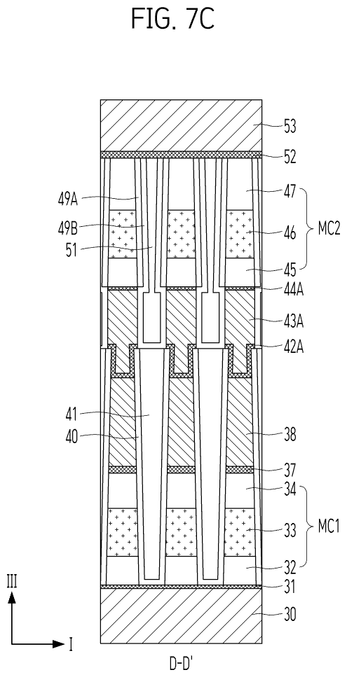

Referring to FIGS. 7A to 7C, the resistance layer 44, the second conductive layer 43, and the resistance layer 42 are etched using the hard mask patterns 48 as etching barriers. Through this, a resistance pattern 44A, a second column line 43A, and a resistance pattern 42A that extend in the second direction II may be formed. The second column line 43A may include a first portion located inside the opening OP and a second portion located outside the opening OP and having a greater width than the first portion.

The resistance pattern 42A may be located between the first column line 38 and the second column line 43A, and may cover the first portion of the second column line 43A. The resistance pattern 42A may include a material having a higher resistivity than the first and second column lines 38 and 43A. As an example, the first and second column lines 38 and 43A may each include tungsten (W), molybdenum (Mo), or the like, and the resistance pattern 42A may include at least one of tungsten nitride (WN), tungsten silicon nitride (WSiN), molybdenum nitride (MoN), molybdenum silicon nitride (MoSiN), titanium nitride (TiN), or titanium chloride (TiCl₄).

Subsequently, a liner layer and a gap-fill insulating layer may be formed, and a planarization process may be performed so that the second cell lines CE2 are exposed. Through this, third liner patterns 49B and third gap-fill insulating layers 51 may be formed.

Subsequently, a resistance layer and a third conductive layer may be formed above the second cell lines CE2. Subsequently, second row lines 53 extending in the first direction I may be formed by etching the third conductive layer, and resistance patterns 52 may be formed by etching the resistance layer. Subsequently, second memory cells MC2 arranged in the first direction I and the second direction II may be formed by etching the second cell lines CE2.

Subsequently, fourth liner patterns 54 may be formed on sidewalls of the second row lines 53 and sidewalls of the second memory cells MC2, and fourth gap-fill insulating layers 55 may be formed.

According to the method described above, the second column line 43A may be formed using the opening OP formed by removing the hard mask pattern 39. Accordingly, it is possible to reduce damage to the second liner patterns 40 in a process of forming the second memory cells MC2 and the second column lines 43A. Specifically, the hard mask patterns 39 are selectively removed compared to the second liner patterns 40 and the second gap-fill insulating layers 41. As a result, the first column lines 38 may be exposed without damaging the second liner patterns 40. The second liner patterns 40 may not be damaged by the source gas used to etch the second conductive layer 43. Because the resistance pattern 42A is formed in the opening OP, a width of the first portion of the second column line 43A may be reduced. Accordingly, contact resistance between the first column line 38 and the second column line 43A may be increased, and damage to the first and second memory cells MC1 and MC2 due to a spike current may be reduced.

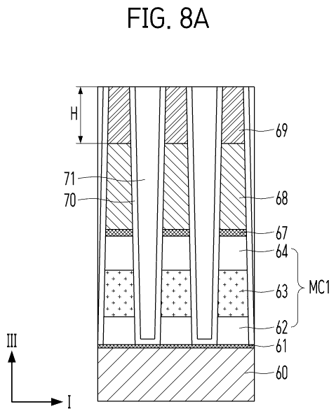

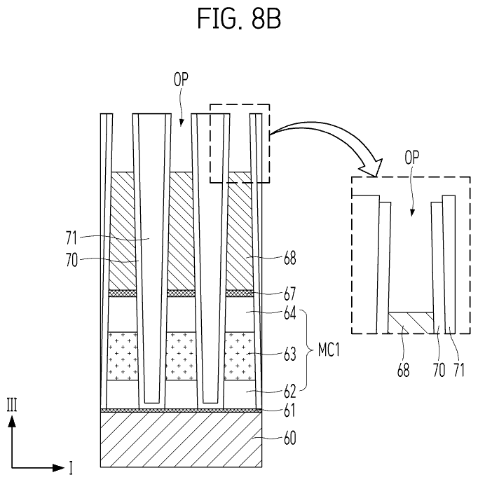

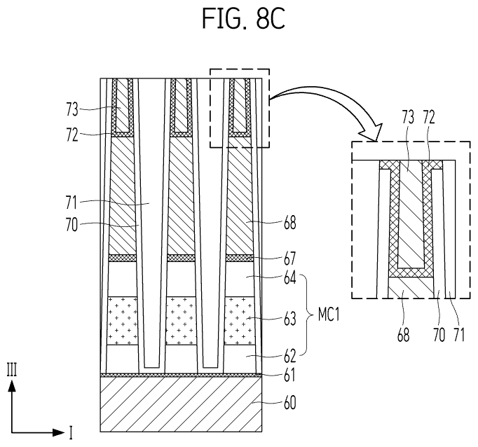

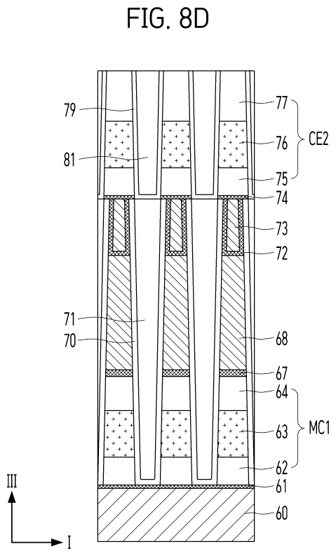

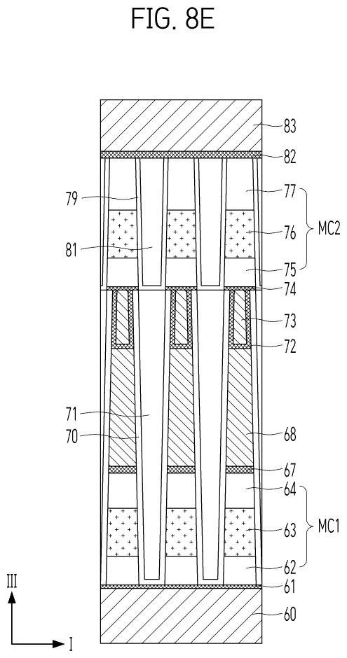

FIGS. 8A to 8E are diagrams for describing a method of manufacturing a semiconductor device in accordance with an embodiment. Hereinafter, the content overlapping with the previously described content may be omitted for the interest of brevity.

Referring to FIG. 8A, first row lines 60 and resistance patterns 61 extending in the first direction I may be formed. First column lines 68, hard mask patterns 69, and resistance patterns 67 extending in the second direction II may be formed. First memory cells MC1 arranged in the first direction I and the second direction II may be formed. The first memory cell MC1 may include a first electrode 62, a variable resistance layer 63, and a second electrode 64. Second liner patterns 70 and second gap-fill insulating layers 71 may be formed. The second liner pattern 70 may be formed on a sidewall of the first memory cell MC1, a sidewall of the first column line 68, and a sidewall of the hard mask pattern 69.

Regions where second column lines are to be formed in a subsequent process may be secured through the hard mask patterns 69. Accordingly, a height H of the hard mask patterns 69 may be adjusted according to a target height of the second column line.

Referring to FIG. 8B, openings OP may be formed between the second liner patterns 70 by removing the hard mask pattern 69. The openings OP may be located between the second gap-fill insulating layers 71 adjacent to each other in the first direction I. The first column lines 68 may be exposed by the openings OP.

For reference, the second liner patterns 70 may be partially etched in a process of etching the hard mask pattern 69. In such a case, upper surfaces of the second liner patterns 70 may be located lower than upper surfaces of the second gap-fill insulating layers 71, and sidewalls of the second gap-fill insulating layers 71 may be exposed by the openings OP.

Referring to FIG. 8C, a resistance pattern 72 and a second column line 73 may be formed in the opening OP. A resistance layer may be formed along surfaces of the first column lines 68, the second liner patterns 70, and the second gap-fill insulating layers 71 exposed through the openings OP, and a conductive layer filling the openings OP may be formed on the resistance layer. Subsequently, the resistance patterns 72 and the second column lines 73 may be formed by planarizing the conductive layer and the resistance layer so that the surfaces of the second gap-fill insulating layers 71 are exposed. A planarization process may be performed by a chemical mechanical polishing (CMP) method. An upper surface of the second column line 73, the upper surface of the second liner pattern 70, and the upper surface of the second gap-fill insulating layer 71 may be located at substantially the same level.

In some embodiments (e.g., the embodiment in FIG. 8C), the upper surfaces of the second liner patterns 70 may be located lower than the upper surfaces of the second gap-fill insulating layers 71. In such a case, the resistance pattern 72 may cover the upper surfaces of the second liner patterns 70. In addition, upper surfaces of the resistance pattern 72, the upper surface of the second column line 73, and the upper surfaces of the second gap-fill insulating layers 71 may be located at substantially the same level.

Referring to FIG. 8D, resistance patterns 74 and second cell lines CE2 extending in the second direction II may be formed. Each of the second cell lines CE2 may include a first electrode 75, a variable resistance layer 76, and a second electrode 77. Subsequently, third liner patterns 79 and third gap-fill insulating layers 81 may be formed.

Referring to FIG. 8E, a resistance layer and a third conductive layer may be formed above the second cell lines CE2 and the third gap-fill insulating layers 81. Subsequently, second row lines 83 and resistance patterns 82 extending in the first direction I may be formed by etching the third conductive layer and the resistance layer. Subsequently, second memory cells MC2 arranged in the first direction I and the second direction II may be formed by etching the second cell lines CE2.

According to the method described above, the resistance pattern 72 may be formed between the first column line 68 and the second column line 73, and the second column line 73 having a smaller width than the first column line 68 may be formed. Accordingly, contact resistance between the first column line 68 and the second column line 73 may be increased, and a spike current may be reduced.

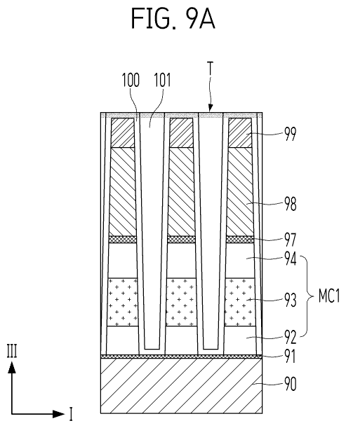

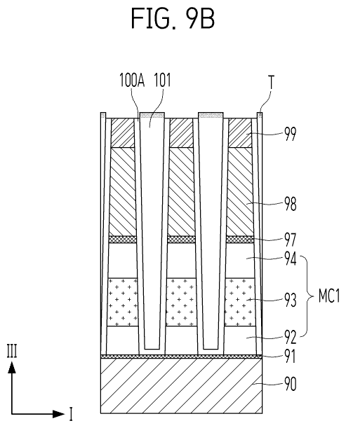

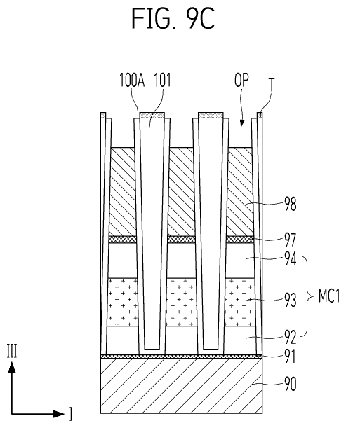

FIGS. 9A to 9C are diagrams for describing a method of manufacturing a semiconductor device in accordance with an embodiment. Hereinafter, the content overlapping with the previously described content may be omitted for the interest of brevity.

Referring to FIG. 9A, first row lines 90 and resistance patterns 91 extending in the first direction I may be formed. First column lines 98, hard mask patterns 99, and resistance patterns 97 extending in the second direction II may be formed. First memory cells MC1 arranged in the first direction I and the second direction II may be formed. The first memory cell MC1 may include a first electrode 92, a variable resistance layer 93, and a second electrode 94.

Subsequently, a second liner layer 100 and second gap-fill insulating layers 101 may be formed. The second liner layer 100 may be formed along surfaces (e.g., sidewalls) of the first memory cells MC1, surfaces (e.g., sidewalls) of the first column lines 98, and surfaces (e.g., sidewalls and upper surfaces) of the hard mask patterns 99. Each of the second gap-fill insulating layers 101 may be formed between a pair of the first column lines 98 adjacent to each other in the first direction I. In addition, the second liner layer 100 may be formed along sidewalls and upper surfaces of the hard mask patterns 99.

Subsequently, a surface treatment process may be performed. The surface treatment process may be performed on the second liner layer 100 and the second gap-fill insulating layers 101. Portions of the second liner layer 100 formed on the upper surfaces of the hard mask patterns 99 may be surface-treated. Upper surfaces of the second gap-fill insulating layers 101 may be surface-treated. As an example, the surface treatment process may be performed using an inert gas such as argon (Ar) or helium (He). The portion T that is surface-treated may have a higher density than a portion that is not surface-treated. For example, the surface treatment may increase a density of upper portions of the second gap-fill insulating layers 101 on which the surface treatment has been performed.

Referring to FIG. 9B, second liner patterns 100A may be formed by etching an upper surface of the second liner layer 100. The portions of the second liner layer 100 formed on the upper surfaces of the hard mask patterns 99 may be removed. As an example, the second liner layer 100 (e.g., the surface-treated portions of the second linear layer 100) may be selectively etched using an etching selectivity between the second liner layer 100 and the second gap-fill insulating layer 101. By soft-etching the second liner layer 100, the hard mask pattern 99 may be exposed. In addition, a polymer, which is an etching byproduct, may be deposited on surfaces of the second gap-fill insulating layers 101.

Referring to FIG. 9C, an opening OP may be formed by removing the hard mask pattern 99. For example, each of a plurality of openings OP may be formed between an adjacent pair of the second gap-fill insulating layers 101 in the first direction I by removing a corresponding one of the hard mask patterns 99. As the surface of the second gap-fill insulating layer 101 is strengthened by the surface treatment, the hard mask pattern 99 may be selectively etched under a condition in which an etching selectivity with respect to the hard mask pattern 99 is high. In a process of etching the hard mask pattern 99, the polymer deposited on the surface of the second gap-fill insulating layer 101 may protect the second gap-fill insulating layer 101.

Subsequently, a process such as forming a second column line in the opening OP may be performed.

According to the method described above, the surfaces of the second gap-fill insulating layers 101 may be strengthened by the surface treatment process. In addition, in the process of etching the hard mask patterns 99, the polymer deposited on the surface of surfaces of the second gap-fill insulating layers 101 may further protect the second gap-fill insulating layers 101. Accordingly, the hard mask pattern 99 may be selectively etched, and the opening OP exposing the first column line 98 may be formed.

Although some embodiments according to the technical idea of the present disclosure have been described above with reference to the accompanying drawings, various embodiments of the present disclosure are not limited to the above-described embodiments. Various types of substitutions, modifications, changes, and combinations for the embodiments may be made by those skilled in the art, to which the present disclosure pertains, and these substitutions, modifications, changes, and combinations belong to the scope of the present disclosure.

What is claimed is:

1. A semiconductor device comprising:
a first row line extending in a first direction;
a first column line extending in a second direction that intersects the first direction;
a first memory cell connected between the first row line and the first column line;
a second column line located above the first column line and extending in the second direction; and
a first resistance pattern located between the first column line and the second column line.

2. The semiconductor device of claim 1, further comprising a liner pattern covering a sidewall of the first memory cell, a sidewall of the first column line, and a portion of a sidewall of the second column line.

3. The semiconductor device of claim 2, wherein the second column line comprises:
a first portion covered by the liner pattern and having a first width; and
a second portion having a greater width than the first portion.

4. The semiconductor device of claim 3, wherein the first resistance pattern covers a bottom surface and a sidewall of the first portion.

5. The semiconductor device of claim 1, further comprising a liner pattern covering a sidewall of the first memory cell, a sidewall of the first column line, and a sidewall of the second column line.

6. The semiconductor device of claim 5, wherein an upper surface of the second column line and an upper surface of the liner pattern are located at substantially the same level.

7. The semiconductor device of claim 1, wherein the first resistance pattern extends along a sidewall of the second column line.

8. The semiconductor device of claim 1, wherein the first resistance pattern includes a material having a higher resistivity than the first column line and the second column line.

9. The semiconductor device of claim 8, wherein the first resistance pattern includes at least one of WN, WSiN, MoN, MoSiN, TiN, or TiCl₄.

10. The semiconductor device of claim 1, wherein the second column line is electrically connected to the first column line through the first resistance pattern.

11. The semiconductor device of claim 1, further comprising a second resistance pattern located between the first memory cell and the first column line.

12. The semiconductor device of claim 1, further comprising:
a second row line extending in the first direction; and
a second memory cell connected between the second column line and the second row line.

13. The semiconductor device of claim 12, further comprising a third resistance pattern located between the second column line and the second memory cell.

14. The semiconductor device of claim 1, wherein the first resistance pattern extends along an upper surface of the first column line and a lower surface of the second column line.

15. A method of manufacturing a semiconductor device, the method comprising:
forming a cell line that extends in a first direction and includes a variable resistance layer;
forming a first conductive layer above the cell line;
forming a hard mask pattern on the first conductive layer, the hard mask pattern extending in a second direction that intersects the first direction;
forming a first column line by etching the first conductive layer using the hard mask pattern, the first column line extending in the second direction;
forming a first memory cell by etching the cell line;
forming liner patterns on sidewalls of the first memory cell, sidewalls of the first column line, and sidewalls of the hard mask pattern;
forming an opening between the liner patterns by removing the hard mask pattern;
forming a resistance pattern in the opening; and
forming a second column line in the opening.

16. The method of claim 15, wherein the resistance pattern is formed along a surface of the first column line and surfaces of the liner patterns exposed through the opening.

17. The method of claim 15, wherein the forming of the second column line comprises:
forming a second conductive layer to fill the opening; and
forming the second column line by etching the second conductive layer, the second column line including a first portion located inside the opening and a second portion located outside the opening, the second portion having a greater width than the first portion.

18. The method of claim 15, wherein the forming of the second column line comprises:
forming a second conductive layer to fill the opening; and
forming the second column line by planarizing the second conductive layer.

19. The method of claim 15, wherein the resistance pattern includes a material having a higher resistivity than the first column line and the second column line.

20. The method of claim 19, wherein the resistance pattern includes at least one of WN, WSiN, MoN, MoSiN, TiN, or TiCl₄.
